(19) United States
(12) Patent Application Publication
(10) Pub. No.: US 2025/0143144 A1
(43) Pub. Date: May 1, 2025

(54) DISPLAY DEVICE

(71) Applicant: Samsung Display Co., LTD., Yongin-si (KR)

(72) Inventors: TAEHYEOG JUNG, Yongin-si (KR); BYUNGHOON KANG, Yongin-si (KR); SANGHOON KIM, Yongin-si (KR); JINGYU SIM, Yongin-si (KR); HYUNJI LEE, Yongin-si (KR); SEONGJIN HWANG, Yongin-si (KR)

(21) Appl. No.: 18/761,650

(22) Filed: Jul. 2, 2024

(30) Foreign Application Priority Data
Oct. 30, 2023 (KR) 10-2023-0146721

(51) Int. Cl. H10K 59/80; H10K 77/10; H10K 102/00

(52) U.S. Cl. CPC H10K 59/873; H10K 77/111; H10K 2102/311; H10K 2102/351

(57) ABSTRACT

A display device includes a display panel, a patterned glass disposed on the display panel, where the patterned glass includes a first non-patterned portion, a patterned portion, and a second non-patterned portion which sequentially are arranged in a first direction, a protective layer disposed on the patterned glass, and a first window adhesive layer disposed between the patterned glass and the protective layer. The protective layer has an elastic modulus in a predetermined range, a maximum value of an elastic modulus of the protective layer is constant, and a minimum value thereof varies in proportion to a thickness of the first window adhesive layer.

This application claims priority to Korean Patent Application No. 10-2023-0146721, filed on Oct. 30, 2023, and all the benefits accruing therefrom under 35 U.S.C. § 119, the content of which in its entirety is herein incorporated by reference.

### BACKGROUND

### 1. Field

The disclosure herein relates to a display device.

### 2. Description of the Related Art

Electronic apparatuses may provide information to a user by displaying various images on a display screen thereof. In general, electronic apparatuses display information within an allocated screen. Recently, flexible electronic apparatuses including flexible display panels, which are capable of folding, have been developed. Unlike rigid electronic apparatuses, flexible electronic apparatuses are capable of folding, rolling, or bending. Since flexible electronic apparatuses, which are deformable into various shapes, may be carried regardless of the existing screen size, user's convenience is improved.

An electronic apparatus may include a display panel and a window disposed on the display panel for protecting the display panel. In a flexible electronic apparatus, a plurality of patterns may be defined in the window to secure the flexibility thereof.

### SUMMARY

The disclosure provides a display device with improved folding reliability.

An embodiment of the invention provides a display device including a display panel, a patterned glass disposed on the display panel, where the patterned glass includes a first non-patterned portion, a patterned portion, and a second non-patterned portion, which are sequentially arranged in a first direction, a protective layer disposed on the patterned glass, and a first window adhesive layer disposed between the patterned glass and the protective layer, where the protective layer has an elastic modulus in a predetermined range, a maximum value of an elastic modulus of the protective layer is constant, and a minimum value thereof varies in proportion to a thickness of the first window adhesive layer.

An embodiment of the invention provides a display device including a display panel including a first non-folding region, a folding region, and a second non-folding region, which are sequentially arranged in a first direction, a patterned glass disposed on the display panel, a lower film disposed under the display panel, and a protective film disposed between the display panel and the lower film, where the folding region is folded with respect to a folding axis parallel to a second direction crossing the first direction, when the folding region is folded, the patterned glass, the lower film, and the protective film are folded with respect to the folding axis, and an elastic modulus of the lower film is in inverse proportion to a change rate of a length of the protective film in the first direction before folding and after folding.

### BRIEF DESCRIPTION OF THE DRAWINGS

The above and other features of the invention will become more apparent by describing in further detail embodiments thereof with reference to the accompanying drawings, in which:

FIG. 1 is a perspective view of an electronic apparatus according to an embodiment of the invention;

FIG. 2 illustrates the electronic apparatus illustrated in FIG. 1 in a folded state;

FIG. 3 is an exploded perspective view of an electronic apparatus according to an embodiment of the invention;

FIG. 4 is a cross-sectional view taken along line I-I′ illustrated in FIG. 3;

FIG. 5 illustrates the electronic apparatus illustrated in FIG. 4 in a state of being in-folded with respect to a folding axis;

FIG. 6 illustrates a cross-section of an embodiment of a display panel illustrated in FIG. 3;

FIG. 7 is a plan view of the display panel illustrated in FIG. 6;

FIG. 8 is an enlarged view of a first region A1 in FIG. 4;

FIG. 9 is a patterned glass illustrated in FIG. 8; and

FIG. 10 is a cross-sectional view taken along line II-II′ illustrated in FIG. 9.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. The term “and/or” includes each of and all of one or more combinations of mentioned items.

Spatially relative terms, such as “below”, “beneath”, “lower”, “above”, “upper” and the like, may be used herein for ease of description to describe one element or component's relationship to another element(s) or component(s) as illustrated in the figures. It will be understood that the spatially relative terms are intended to encompass different orientations of the device in use or operation in addition to the orientation depicted in the figures. Like numbers or symbols refer to like elements throughout the specification.

It will be understood that, although the terms first, second, etc. may be used herein to describe various elements, components, and/or sections, these elements, components, and/or sections should not be limited by these terms. These terms are only used to distinguish one element, component, or section from another element, component or section. Thus, a first element, component, or section discussed below could be termed a second element, component, or section without departing from the teachings of the invention.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the invention will be described with reference to a plan view and a cross-sectional view which are schematic illustrations of idealized embodiments. Accordingly, the form of illustrated examples may be modified by manufacturing technologies and/or tolerances, etc. Thus, embodiments of the invention are not limited to the specific shape as illustrated but include deformation generated by the manufacturing process. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

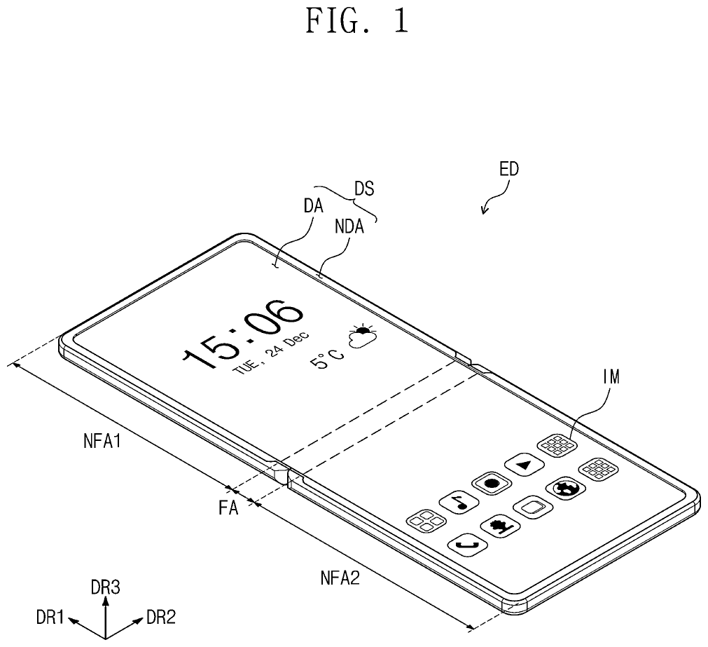

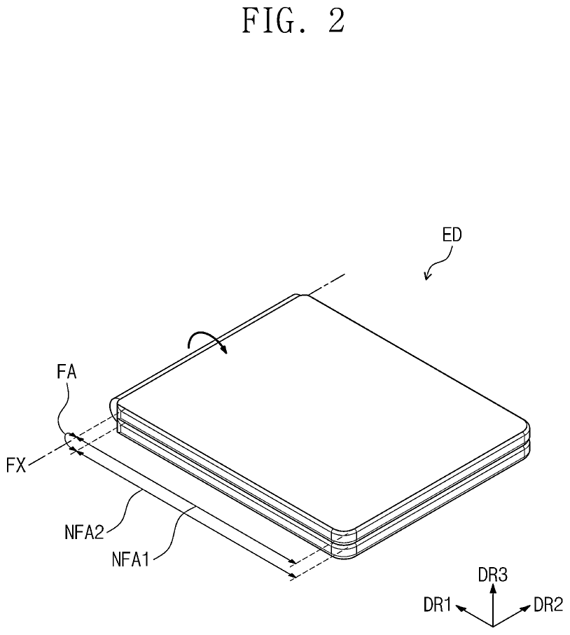

FIG. 1 is a perspective view of an electronic apparatus according to an embodiment of the invention. FIG. 2 illustrates the electronic apparatus illustrated in FIG. 1 in a folded state.

Referring to FIG. 1, an electronic apparatus ED according to an embodiment of the invention may have a rectangular shape which has long sides extending in a first direction DR1 and short sides extending in a second direction DR2 crossing the first direction DR1. However, an embodiment of the invention is not limited thereto, and the electronic apparatus ED may have various shapes such as a circular shape, a polygonal shape, or the like. The electronic apparatus ED may be a flexible electronic apparatus.

Hereinafter, a crossing direction substantially perpendicular to a plane defined by the first direction DR1 and the second direction DR2 is defined as a third direction DR3. The third direction DR3 may be a thickness direction of the electronic apparatus ED. In addition, in this specification, the wording “when viewed on a plane” may be defined as a state of being viewed in the third direction DR3. Also, the wording “overlapping” means that when viewed on a plane, components overlap each other in the third direction DR3.

The electronic apparatus ED may include a folding region FA and a plurality of non-folding regions NFA1 and NFA2. The non-folding regions NFA1 and NFA2 may include a first non-folding region NFA1 and a second non-folding region NFA2. The folding region FA may be disposed between the first non-folding region NFA1 and the second non-folding region NFA2. The first non-folding region NFA1, the folding region FA, and the second non-folding region NFA2 may be arranged in the first direction DR1.

In an embodiment, for example, one folding region FA and two non-folding regions NFA1 and NFA2 may be defined as illustrated in FIG. 1, but the number of folding region FA and the number of non-folding regions NFA1 and NFA2 are not limited thereto. In an embodiment, for example, the electronic apparatus ED may include more than two non-folding regions and a plurality of folding regions disposed between the non-folding regions.

A top surface of the electronic apparatus ED may be defined as a display surface DS, and may have a flat surface defined by the first direction DR1 and the second direction DR2. An image IM generated in the electronic apparatus ED may be provided to a user through the display surface DS.

The display surface DS may include a display region DA and a non-display region NDA around the display region DA. The display region DA may display an image, and the non-display region NDA may not display an image. The non-display region NDA may surround the display region DA, and may define an edge of the electronic apparatus ED which is printed in a predetermined color.

Although not illustrated, the electronic apparatus ED may have a plurality of sensors and at least one camera.

Referring to FIG. 2, an embodiment of the electronic apparatus ED may be a foldable electronic apparatus ED which is folded or unfolded. In an embodiment, for example, the electronic apparatus ED may be folded in a way such that the folding region FA is bent with respect to a folding axis FX parallel to the second direction DR2. In such an embodiment where the electronic apparatus ED is foldable, the folding axis FX may be defined as a short axis parallel to the short side of the electronic apparatus ED.

When the electronic apparatus ED is folded, the electronic apparatus ED may be in-folded such that the first non-folding region NFA1 and the second non-folding region NFA2 may face each other and the display surface DS is not exposed to the outside. However, an embodiment of the invention is not limited thereto. In an embodiment, for example, the electronic apparatus ED may be out-folded with respect to the folding axis FX such that the display surface DS is exposed to the outside.

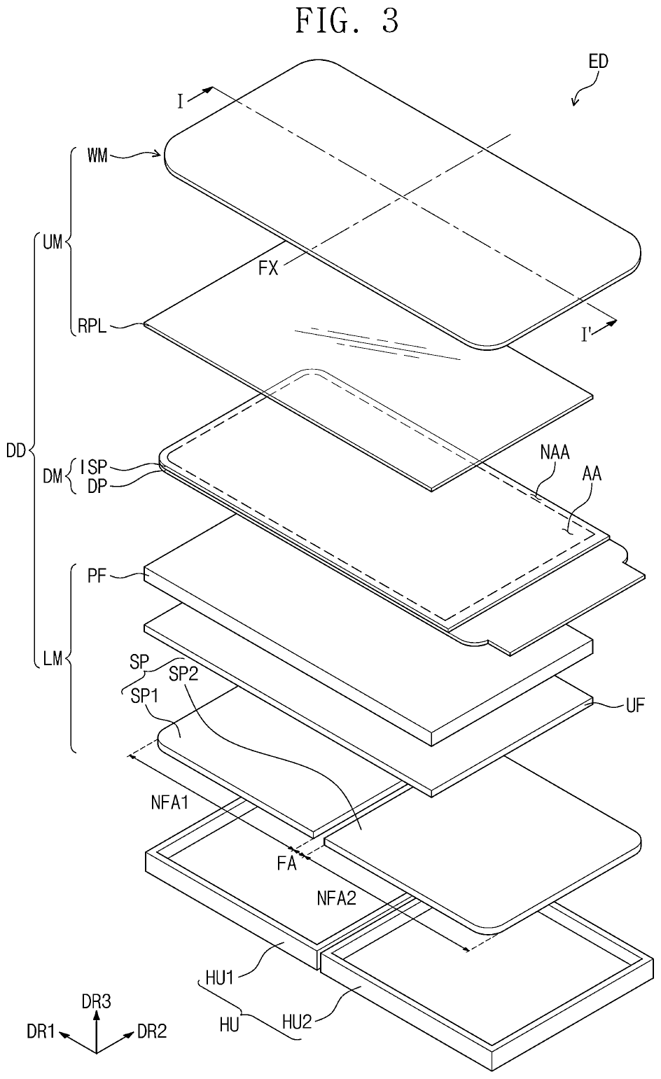

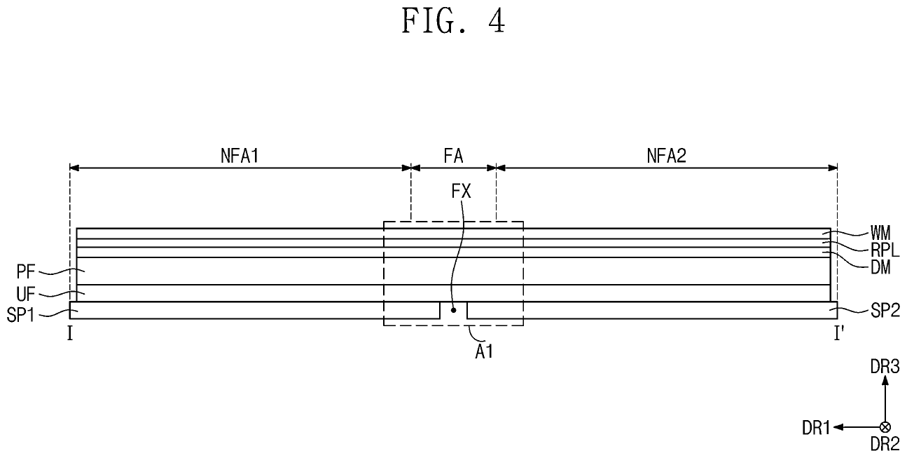

FIG. 3 is an exploded perspective view of an electronic apparatus according to an embodiment of the invention. FIG. 4 is a cross-sectional view taken along line I-I′ illustrated in FIG. 3.

Referring to FIGS. 3 and 4, an embodiment of the electronic apparatus ED may include a display device DD and a housing HU. Although not illustrated, the electronic apparatus ED may further include a mechanical structure (e.g., a hinge) for controlling a folding operation of the display device DD.

The display device DD according to an embodiment of the invention may include a display module DM for displaying an image, an upper module UM disposed on the display module DM, and a lower module LM disposed under the display module DM. The display module DM may constitute a part of the display device DD, and in particular, an image may be generated by the display module DM. The display module DM may display an image in response to an electrical signal, and may transmit/receive information about an external input. The display module DM may be defined by an active region AA and a peripheral region NAA. The active region AA may be defined as a region that displays an image which is provided by the display module DM.

The peripheral region NAA may be adjacent to the active region AA. In an embodiment, for example, the peripheral region NAA may surround the active region AA. However, this is illustrated as an example, and the peripheral region NAA may be defined as various shapes and is not limited to any one embodiment. According to an embodiment, the active region AA of the display module DM may overlap at least a portion of the display region DA in FIG. 1.

The display module DM may include a display panel DP and an input sensing unit ISP. The display panel DP according to an embodiment of the invention may be an emission-type display panel, but is not particularly limited. In an embodiment, for example, the display panel DP may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, etc. Hereinafter, for convenience of description, embodiments where the display panel DP is an organic light-emitting display panel will be described.

The display panel DP may be a flexible display panel. Accordingly, the display panel DP may be entirely rolled, or may be folded or unfolded with respect to the folding axis FX.

In an embodiment, the input sensing unit ISP may be disposed directly on the display panel DP. According to an embodiment of the invention, the input sensing unit ISP may be formed on the display panel DP through a continuous process. In such an embodiment, where the input sensing unit ISP is disposed directly on the display panel DP, an adhesive film is not disposed between the input sensing unit ISP and the display panel DP. However, an embodiment of the invention is not limited thereto. In another embodiment, an adhesive film may be disposed between the input sensing unit ISP and the display panel DP. In such an embodiment, the input sensing unit ISP may not be manufactured through a continuous process together with the display panel DP, but manufactured through a separate process from the display panel DP, and then fixed (or attached) to a top surface of the display panel DP via an adhesive film.

The display panel DP generates an image, and the input sensing unit ISP acquires coordinate information about a user's input (for example, a touch event).

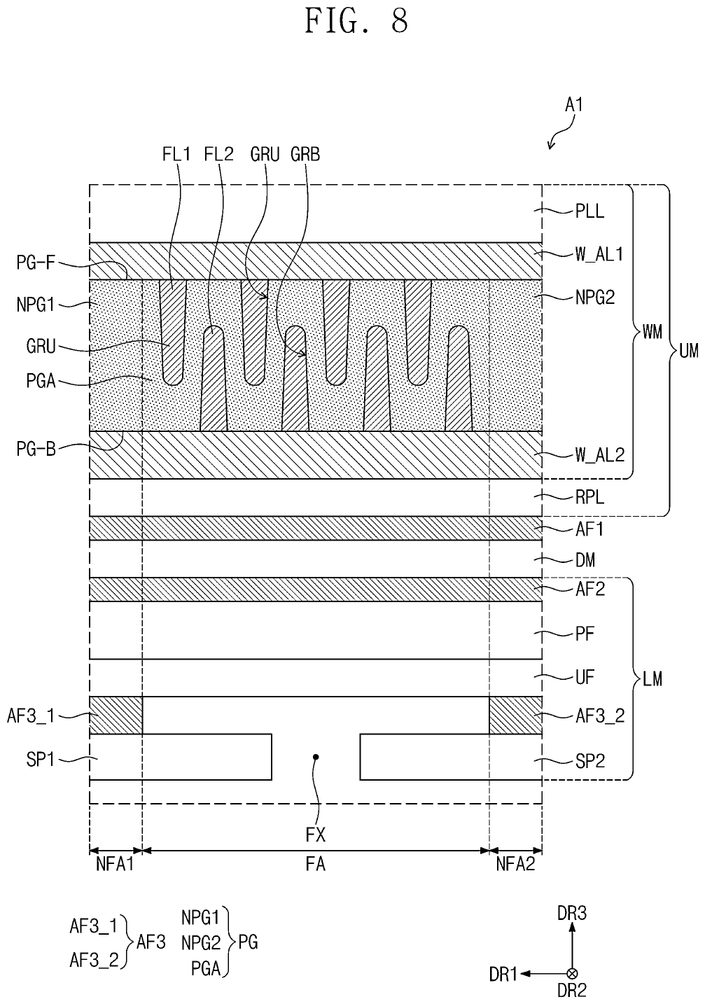

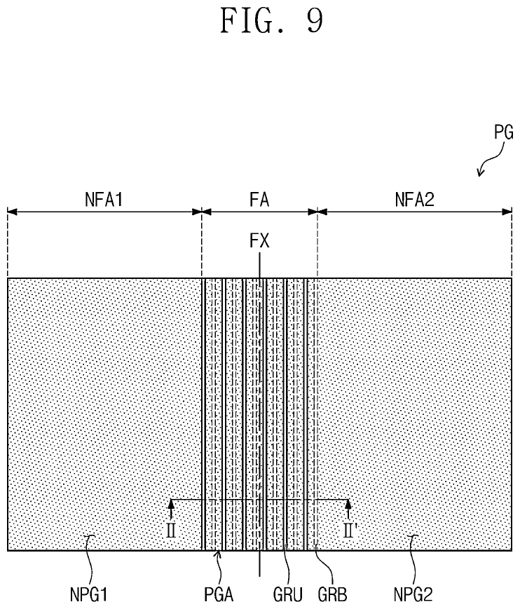

The upper module UM may include a window WM disposed on the display module DM. The window WM may include an optically transparent insulating material. Accordingly, an image generated by the display module DM may pass through the window WM and may be easily perceived by a user. The window WM will be described later in greater detail with reference to FIG. 8.

The upper module UM may further include one or more functional layer disposed between the display module DM and the window WM. In an embodiment of the invention, a functional layer may be an anti-reflective layer RPL for blocking external light reflection.

The anti-reflective layer RPL may prevent elements constituting the display module DM from being viewed from the outside due to external light which is incident through a front surface of the display device DD. The anti-reflective layer RPL may include a phase retarder and a polarizer. The phase retarder may be a film type or a liquid crystal coating type, and may include a λ/2 phase retarder and/or a λ/4 phase retarder. The polarizer may also be a film type or a liquid crystal coating type. The film-type polarizer may include a stretchable synthetic resin film, and the liquid crystal coating-type polarizer may include liquid crystals arranged in a predetermined arrangement. The phase retarder and the polarizer may be provided as a single polarizing film. The functional layer may further include a protective film disposed on an upper part or a lower part of the anti-reflective layer RPL.

The lower module LM may include a support plate SP disposed on a rear surface of the display module DM to support the display module DM, a protective film PF disposed between the display module DM and the support plate SP, and a lower film UF disposed between the protective film PF and the support plate SP. The support plate SP may include support plates, the number of which corresponds to that of the non-folding regions NFA1 and NFA2. In an embodiment of the invention, the support plate SP may include a first support plate SP1 and a second support plate SP2 disposed to be spaced apart from the first support plate SP1.

The first and second support plates SP1 and SP2 may be disposed to respectively correspond to the first and second non-folding regions NFA1 and NFA2. The first support plate SP1 is disposed overlapping the first non-folding region NFA1 of the display module DM, and the second support plate SP2 is disposed overlapping the second non-folding region NFA2 of the display module DM. The first and second support plates SP1 and SP2 may each include a metal material or a plastic material.

In a state where the display module DM is unfolded as illustrated in FIG. 1, the first and second support plates SP1 and SP2 are disposed spaced apart from each other in the first direction DR1. In a state where the display module DM is folded with respect to the folding axis FX as illustrated in FIG. 2, the first and second support plates SP1 and SP2 may be disposed spaced apart from each other in the third direction DR3.

The first and second support plates SP1 and SP2 may be spaced apart by a gap corresponding to the folding region FA. The first and second support plates SP1 and SP2 may partially overlap the folding region FA. That is, a spaced distance between the first support plate SP1 and the second support plate SP2 in the first direction DR1 may be less than the width of the folding region FA.

Although not illustrated, the support plate SP may further include a connection module for connecting the first and second support plates SP1 and SP2. The connection module may include a hinge module or a multi-joint module.

In an embodiment, as shown in FIG. 3, the support plate SP has two support plates SP1 and SP2, but an embodiment of the invention is not limited thereto. In an embodiment, where a plurality of folding axes FX are provided, the support plate SP may have a plurality of support plates divided with respect to the plurality of folding axes FX. Alternatively, the support plate SP may not be divided into the first and second support plates SP1 and SP2, and may be provided in an integrated shape. In this case, a bending portion corresponding to the folding region FA may be provided to or defined in the support plate SP. In the bending portion, openings may be formed or defined through the support plate SP may be provided or a groove recessed from one surface of the support plate SP may be provided.

The protective film PF may be disposed between the display module DM and the support plate SP. The protective film PF may be disposed under the display module DM and may protect a rear surface of the display module DM. The protective film PF may include a synthetic resin film, and for example, may be a polyimide film or a polyethylene terephthalate film. However, this is an example, and the protective film PF is not limited to the above example.

The lower film UF may be disposed between the protective film PF and the support plate SP. The lower film UF may include a flexible plastic material such as polyimide (PI). The lower film UF will be described later in greater detail with reference to FIG. 8.

The housing HU may accommodate the display device DD, and in particular, the housing HU may accommodate the display module DM and the lower module LM while being coupled with the window WM. In an embodiment, as shown in FIG. 3, the housing HU includes first and second housings HU1 and HU2 which are separated from each other, but an embodiment of the invention is not limited thereto. Although not illustrated, the electronic apparatus ED may further include a hinge structure to connect the first and second housings HU1 and HU2.

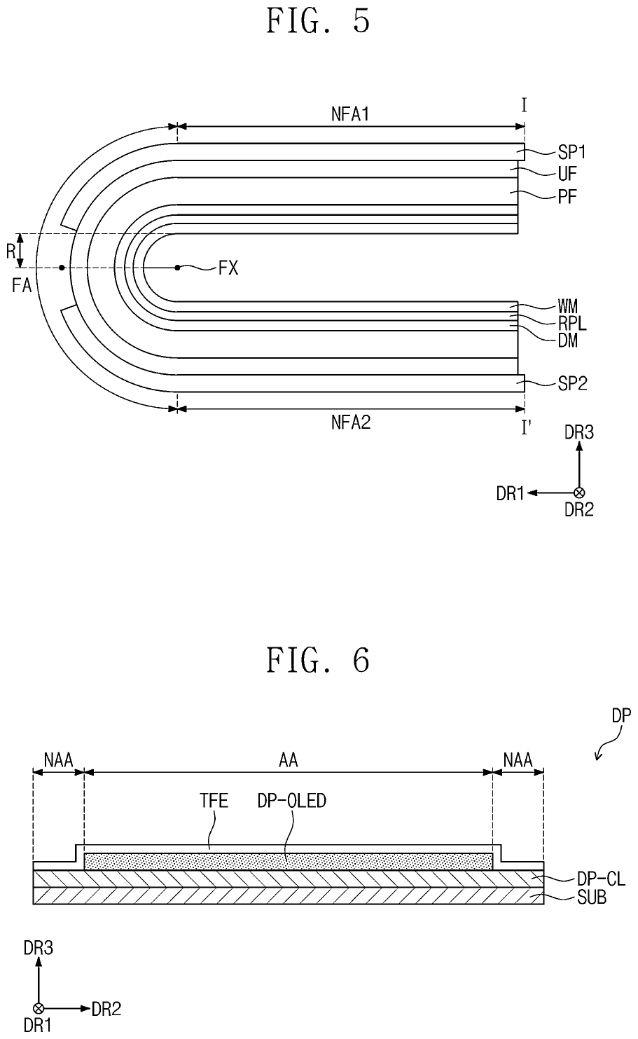

FIG. 5 illustrates the electronic apparatus illustrated in FIG. 4 in a state of being in-folded with respect to a folding axis.

Referring to FIGS. 4 and 5, the folding region FA may be folded. The folding region FA may be bent into a curve. The folding region FA may be bent with a radius of curvature R. The radius of curvature R may be defined as the shortest distance between the folding axis FX and the window WM. The radius of curvature R may be in a range of about 1.0 millimeter (mm) to about 2.0 mm. In an embodiment, for example, the radius of curvature R may be about 1.0 mm, but an embodiment of the invention is not limited thereto.

When the folding region FA is in a folded state, a portion of the window WM and a portion of the lower film UF, which overlap the folding region FA, may be bent. The folding region FA may be subjected to folding and unfolding operations repeatedly. When the folding region FA is folded and unfolded, the portion of the window WM and the portion of the lower film UF may assume a bent state and a flat state, repeatedly.

The thickness and elastic modulus of each of the portion of the window WM and the portion of the lower film UF may be set depending on the radius of curvature R. The thickness and elastic modulus of each of the portion of the window WM and the portion of the lower film UF will be described later in greater detail with reference to FIG. 8.

FIG. 6 illustrates a cross-section of an embodiment of a display panel illustrated in FIG. 3.

By way of example, FIG. 6 illustrates a cross-section of a display panel DP when viewed in the first direction DR1.

Referring to FIG. 6, an embodiment of the display panel DP may include a substrate SUB, a circuit element layer DP-CL disposed on the substrate SUB, a display element layer DP-OLED disposed on the circuit element layer DP-CL, and a thin film encapsulation layer TFE covering the display element layer DP-OLED.

The substrate SUB may include an active region AA and a peripheral region NAA around the active region AA. The substrate SUB may include a flexible plastic material such as polyimide (PI). The display element layer DP-OLED may be disposed on the active region AA.

A plurality of pixels may be disposed in the active region AA. The pixels may each include a light-emitting element disposed in the display element layer DP-OLED and connected to a transistor disposed on the circuit element layer DP-CL.

The thin film encapsulation layer TFE may be disposed on the circuit element layer DP-CL to cover the display element layer DP-OLED. The thin film encapsulation layer TFE may include inorganic layers and an organic layer between the inorganic layers. The inorganic layers may protect the pixels from moisture/oxygen. The organic layer may protect the pixels PX from foreign matters such as dust particles.

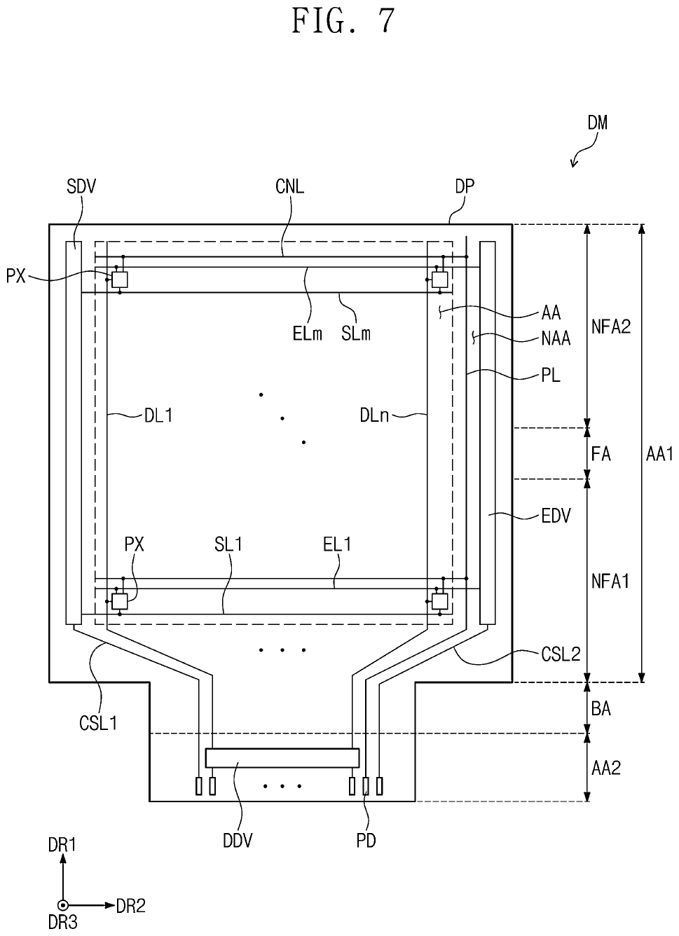

FIG. 7 is a plan view of the display panel illustrated in FIG. 6.

Referring to FIG. 7, an embodiment of the display module DM may include a display panel DP, a scan driver SDV, a data driver DDV, and an emission driver EDV.

The display panel DP may include a first region AA1, a second region AA2, and a bending region BA between the first region AA1 and the second region AA2. The bending region BA may extend in the second direction DR2, and the first region AA1, the bending region BA, and the second region AA2 may be arranged in the first direction DR1.

The first region AA1 may include the active region AA and the peripheral region NAA around the active region AA. The peripheral region NAA may surround the active region AA. The active region AA may be a region in which an image is displayed, and the peripheral region NAA may be region in which an image is not displayed. The second region AA2 and the bending region BA may be regions in which an image is not displayed.

When viewed in the second direction DR2, the first region AA1 may include a first non-folding region NFA1, a second non-folding region NFA2, and a folding region FA between the first non-folding region NFA1 and the second non-folding region NFA2.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a power supply line PL, a plurality of connection lines CNL, and a plurality of pads PD. Here, m and n are natural numbers. The pixels PX may be disposed in the active region AA, and connected to the scan lines SL1 to SLm, the data lines DL1 to DLn, and the emission lines EL1 to ELm.

The scan driver SDV and the emission driver EDV may be disposed in the peripheral region NAA. The scan driver SDV and the emission driver EDV may be disposed in portions of the peripheral region NAA respectively adjacent to both sides of the first region AA1 which are opposite to each other in the second direction DR2. The data driver DDV may be disposed in the second region AA2. In an embodiment, the data driver DDV may be manufactured in the form of an integrated circuit chip and mounted on the second region AA2.

The scan lines SL1 to SLm may extend in the second direction DR2 and may be connected to the scan driver SDV. The data lines DL1 to DLn may extend in the first direction DR1, and may be connected to the data driver DDV via the bending region BA. The emission lines EL1 to ELm may extend in the second direction DR2 and may be connected to the emission driver EDV.

The power supply line PL may extend in the first direction DR1 and may be disposed in the peripheral region NAA. The power supply line PL may be disposed between the active region AA and the emission driver EDV. However, an embodiment of the invention is not limited thereto, and the power supply line PL may also be disposed between the active region AA and the scan driver SDV.

The power supply line PL may extend to the second region AA2 via the bending region BA. The power supply line PL, when viewed on a plane, may extend toward a lower end of the second region AA2. The power supply line PL may receive a driving voltage.

The connection lines CNL may extend in the second direction DR2 and may be arranged in the first direction DR1. The connection lines CNL may be connected to the power supply line PL and the pixels PX. A driving voltage may be applied to the pixels PX through the power supply line PL and the connection lines CNL which are connected to each other.

The first control line CSL1 may be connected to the scan driver SDV, and may extend toward the lower end of the second region AA2 via the bending region BA. The second control line CSL2 may be connected to the emission driver EDV, and may extend toward the lower end of the second region AA2 via the bending region BA. The data driver DDV may be disposed between the first control line CSL1 and the second control line CSL2.

When viewed on a plane, the pads PD may be disposed adjacent to the lower end of the second region AA2. The data driver DDV, the power supply line PL, the first control line CSL1, and the second control line CSL2 may be connected to the pads PD.

The data lines DL1 to DLn may be connected to the corresponding pads PD respectively through the data driver DDV. In an embodiment, for example, the data lines DL1 to DLn may be connected to the data driver DDV, and the data driver DDV may be connected to the pads PD respectively corresponding to the data lines DL1 to DLn.

Although not illustrated, a printed circuit board may be connected to the pads PD, and a timing controller and a voltage generator may be disposed on the printed circuit board. The timing controller may be manufactured as an integrated circuit chip and mounted on the printed circuit board. The timing controller and the voltage generator may be connected to the pads PD through the printed circuit board.

The timing controller may control operations of the scan driver SDV, the data driver DDV, and the emission driver EDV. The timing controller may generate a scan control signal, a data control signal, and an emission control signal in response to control signals received from the outside. The voltage generator may generate a driving voltage.

The scan control signal may be provided to the scan driver SDV through the first control line CSL1. The emission control signal may be provided to the emission driver EDV through the second control line CSL2. The data control signal may be provided to the data driver DDV. The timing controller may receive image signals from the outside, and convert a data format of the image signals to comply with specifications of interface with the data driver DDV and provide the converted result to the data driver DDV.

The scan driver SDV may generate a plurality of scan signals in response to the scan control signal. The scan signals may be applied to the pixels PX through the scan lines SL1 to SLm. The scan signals may be applied sequentially to the pixels PX.

The data driver DDV may generate, in response to the data control signal, a plurality of data voltages corresponding to the image signals. The data voltages may be applied to the pixels PX through the data lines DL1 to DLn. The emission driver EDV may generate a plurality of emission signals in response to the emission control signal. The emission signals may be applied to the pixels PX through the emission lines EL1 to ELm.

The pixels PX may receive the data voltages in response to the scan signals. The pixels PX may display images by emitting light with a luminance corresponding to the data voltages in response to the emission signals. The emission time of the pixels PX may be controlled by the emission signals.

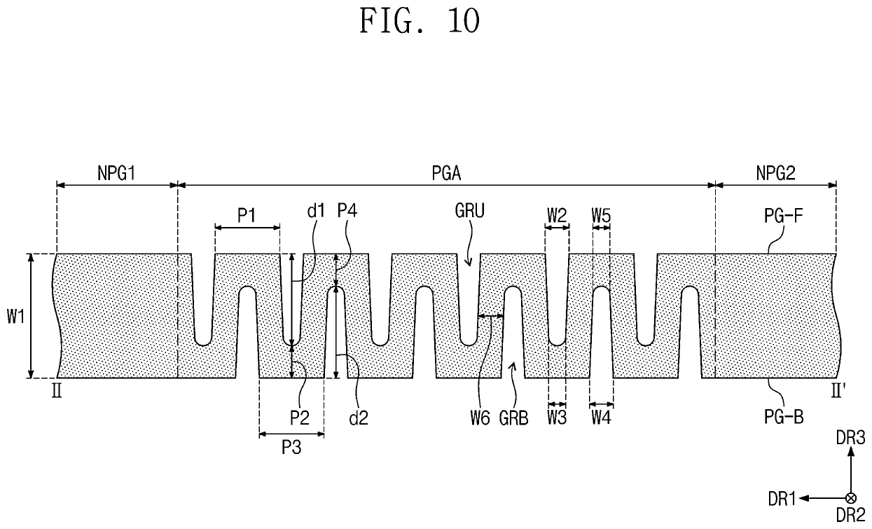

FIG. 8 is an enlarged view of a first region A1 in FIG. 4. FIG. 9 is a patterned glass illustrated in FIG. 8. FIG. 10 is a cross-sectional view taken along line II-II′ illustrated in FIG. 9.

Particularly, FIG. 8 is a cross-sectional view, of the first region A1 in FIG. 4, and FIG. 9 is a plan view of the patterned glass PG.

In FIGS. 8 to 10, first and second support plates SP1 and SP2, an anti-reflective layer RPL, a protective film PF, and a display module DM in FIG. 8 are the same as the first and second support plates SP1 and SP2, the anti-reflective layer RPL, the protective film PF, and the display module DM described above with reference to FIGS. 3 and 4, any repetitive detailed description thereof will be omitted or simplified.

Referring to FIGS. 8, 9, and 10, in an embodiment, a window WM may include a patterned glass PG, a first window adhesive layer W_AL1, a second window adhesive layer W_AL2, a protective layer PLL, and filling patterns FL1 and FL2.

The patterned glass PG may include a glass material. The patterned glass PG may include a patterned portion PGA and first and second non-patterned portions NPG1 and NPG2. The first non-patterned portion NPG1, the patterned portion PGA, and the second non-patterned portion NPG2 may be arranged in the first direction DR1. The patterned portion PGA may be disposed between the first and second non-patterned portions NPG1 and NPG2. Substantially, the first non-patterned portion NPG1, the patterned portion PGA, and the second non-patterned portion NPG2 may be integrally formed as a single unitary indivisible part.

The patterned portion PGA may overlap the folding region FA. The first non-patterned portion NPG1 may overlap the first non-folding region NFA1. The second non-patterned portion NPG2 may overlap the second non-folding region NFA2.

The patterned glass PG may include a top surface PG-F and a bottom surface PG-B. The top surface PG-F and the bottom surface PG-B may mean two surfaces, of the patterned glass PG, opposite to each other in the third direction DR3. The bottom surface PG-B of the patterned glass PG may be defined as a surface facing the anti-reflective layer RPL.

A first width W1 may be a distance between the top surface PG-F and the bottom surface PG-B. That is, the first width W1 may correspond to a thickness (or a maximum thickness) of the patterned glass PG. The first width W1 may be in a range of about 100 micrometers (μm) to about 175 μm.

A plurality of first grooves GRU and a plurality of second grooves GRB may be defined in the patterned portion PGA. The first grooves GRU may be defined in the top surface PG-F of the patterned glass PG. When viewed on a plane, the first grooves GRU may extend in the second direction DR2, and may be arranged spaced apart from each other in the first direction DR1. The first grooves GRU may each be defined or formed in the third direction DR3 from the top surface PG-F toward the bottom surface PG-B. The first grooves GRU may be recessed by more than one half of the thickness of the patterned glass PG (or the first width W1). The first grooves GRU may each have a depth which is greater than one half of the thickness of the patterned glass PG.

The first grooves GRU may have a downwardly concave shape. A second width W2 of the upper end of each of the first grooves GRU, adjacent to the top surface PG-F of the patterned glass PG may be greater than a third width W3 of the lower end of each of the first grooves GRU, adjacent to the bottom surface PG-B of the patterned glass PG. Bottom surfaces of the first grooves GRU may have curved surfaces.

The second grooves GRB may be defined in the bottom surface PG-B of the patterned glass PG. When viewed on a plane, the second grooves GRB may extend in the second direction DR2, and may be arranged spaced apart from each other in the first direction DR1. The second grooves GRB may each defined or formed in the third direction DR3 from the bottom surface PG-B toward the top surface PG-F. The second grooves GRB may extend by more than one half of the thickness of the patterned glass PG. The second grooves GRB may each have a depth which is greater than one half of the thickness of the patterned glass PG.

The second grooves GRB may have an upwardly convex shape. A fourth width W4 of the lower end of each of the second grooves GRB, adjacent to the bottom surface PG-B of the patterned glass PG may be greater than a fifth width W5 of the upper end of each of the second grooves GRB, adjacent to the top surface PG-F of the patterned glass PG. Bottom surfaces of the second grooves GRB may have curved surfaces.

in an embodiment, for example, the first grooves GRU and the second grooves GRB may have a same shape as each other. In such an embodiment, the second width W2 may be the same as the fourth width W4, and the third width W3 may be the same as the fifth width W5. However, an embodiment of the invention may not be limited thereto. Alternatively, each of the first grooves GRU may have a different shape from each of the second grooves GRB. In such an embodiment, the second width W2 may be different from the fourth width W4, and the third width W3 may be different from the fifth width W5.

The sizes of the first to fifth widths W1 to W5 may be determined depending on folding properties. In addition, the sizes of the second and third widths W2 and W3 may be adjusted based on first depths d1 of the first grooves GRU. The sizes of the fourth and fifth widths W4 and W5 may be adjusted based on second depths d2 of the second grooves GRB. In an embodiment of the invention, the first depth d1 may be the same as the second depth d2. Alternatively, the first depth d1 may be different from the second depth d2.

When viewed in the second direction DR2, the first grooves GRU and the second grooves GRB may be alternately defined in an inverse form. The first grooves GRU and the second grooves GRB may not overlap each other. In an embodiment, for example, the first grooves GRU may be spaced apart by a first gap P1 in the first direction DR1. The second grooves GRB may be spaced apart by a third gap P3 in the first direction DR1. Substantially, the first gap P1 and the third gap P3 may be the same as each other. The first grooves GRU and the second grooves GRB which are adjacent to each other in the first direction DR1 may be spaced apart from each other by a sixth width W6.

An elastic modulus of each of the first non-patterned portion NPG1 and the second non-patterned portion NPG 2 may be in a range of about 60 gigapascals (GPa) to about 80 GPa. In an embodiment, for example, the elastic moduli of the first and second non-patterned portions NPG1 and NPG2 may be about 70 GPa. In an embodiment, for example, an elastic modulus of the patterned portion PGA may be in a range of about 30 MPa to about 2000 MPa.

Referring to FIG. 8, the first filling patterns FL1 may be respectively disposed in corresponding first grooves GRU among the first grooves GRU. The second filling patterns FL2 may be respectively disposed in corresponding second grooves GRB among the second grooves GRB.

When viewed in the second direction DR2, the first filling patterns FL1 may be disposed spaced apart from each other in the first direction DR1. When viewed in the second direction DR2, the second filling patterns FL2 may be disposed spaced apart from each other in the first direction DR1. When viewed in the second direction DR2, the first and second filling patterns FL1 and FL2 may be alternately disposed in an inverse form. In FIG. 8, for convenience of illustration, four of the first filling patterns FL1 and four of the second filling patterns FL2 are illustrated, but the numbers of the first and second filling patterns FL1 and FL2 are not limited thereto.

In an embodiment, the first and second filling patterns FL1 and FL2 may include a same material as each other. In an embodiment, for example, the first and second filling patterns FL1 and FL2 may each include a synthetic resin material. The first and second filling patterns FL1 and FL2 may each include a material having the same refractive index as that of the patterned glass PG. In an embodiment, the first and second filling patterns FL1 and FL2 may each include at least one selected from a urethane-based resin, an epoxy-based resin, a polyester-based resin, a polyether-based resin, an acrylate-based resin, an acrylonitrile-butadiene-styrene (ABS) resin, and rubber. In an embodiment, for example, the first and second filling patterns FL1 and FL2 may each include at least one selected from phenylene, polyethylene terephthalate (PET), polyimide (PI), polyamide (PAI), polyethylene naphthalate (PEN), and polycarbonate (PC).

The protective layer PLL may be disposed on the patterned glass PG. The protective layer PLL may perform a function to protect the patterned glass PG from an external impact. The protective layer PLL may include a synthetic resin material. In an embodiment of the invention, the protective layer PLL may include at least one selected from a urethane-based resin, an epoxy-based resin, a polyester-based resin, a polyether-based resin, an acrylate-based resin, an acrylonitrile-butadiene-styrene (ABS) resin, and rubber. In an embodiment, for example, the protective layer PLL may include at least one selected from phenylene, polyethylene terephthalate (PET), polyimide (PI), polyamide (PAI), polyethylene naphthalate (PEN), and polycarbonate (PC).

TABLE 1

| Elastic modulus of | Deformation rate of protective layer by thickness | | | |
|---|---|---|---|---|
| protective layer | 50 μm | 60 μm | 65 μm | 70 μm |
| 5 GPa | 1.9% | 2.4% | 2.8% | 3.1% |

Table 1 shows a deformation rate of the protective layer PLL according to a thickness of the protective layer PLL which is measured at a room temperature (e.g., about 25° C.) when the display device DD (see FIG. 3) is folded. The deformation rate may be defined as a ratio of the change in the length of the protective layer PLL in the first direction DR1 after folding to the length of the protective layer PLL in the first direction DR1 before folding. For example, the deformation rate of the protective layer PLL is indicated when the radius of curvature R (see FIG. 5) is about 1.0 mm during folding. For example, the deformation rate of the protective layer PLL is indicated when the elastic modulus of the protective layer PLL is about 5 GPa.

In an embodiment, the thickness of the protective layer PLL is in a range about 50 μm to about 60 μm. Specifically, when the deformation rate of the protective layer PLL is about 2.5% or greater, a crack may occur in the protective layer PLL. In Table 1, when the thickness of the protective layer PLL is about 60 μm, the deformation rate of the protective layer PLL may be about 2.4%. Accordingly, a maximum value of the thickness of the protective layer PLL may be about 60 μm to effectively prevent the deformation rate of the protective layer PLL from being about 2.5% or more.

In an embodiment, a minimum value of the thickness of the protective layer PLL may be about 50 μm. When the thickness of the protective layer PLL is less than about 50 μm, the impact resistance of the protective layer PLL may be weakened, and thus the function to protect the patterned glass PG from an external impact may be lost. In addition, when the thickness of the protective layer PLL is less than about 50 μm, a buckling may occur in the protective layer PLL when the display device DD (see FIG. 3) is folded, and thus an irreversible physical property change of the protective layer PLL may occur.

Table 1 shows, as an example, the deformation rate of the protective layer PLL when the elastic modulus of the protective layer PLL is about 5 GPa, but the elastic modulus of the protective layer PLL may have a predetermined range. The elastic modulus of the protective layer PLL will be described later.

In an embodiment, as shown in FIG. 8, the first window adhesive layer W_AL1 may be disposed between the patterned glass PG and the protective layer PLL. The first window adhesive layer W_AL1 may be disposed on the top surface PG-F of the patterned glass PG. The first window adhesive layer W_AL1 may be disposed on the bottom surface of the protective layer PLL. The patterned glass PG and the protective layer PLL may be bonded to each other by the first window adhesive layer W_AL1.

The first window adhesive layer W_AL1 may include an optically transparent adhesive material. The first window adhesive layer W_AL1 may include a pressure sensitive adhesive (PSA), an optical clear adhesive (OCA), or an optical clear resin (OCR).

TABLE 2

| | |
|---|---|
| Thickness of first | Elastic modulus of first |
| window adhesive | window adhesive layer (W_AL1) |

| layer (W_AL1) | 50 kPa | 73 kPa | 88 kPa | 127 kPa |
|---|---|---|---|---|
| 25 μm | OK | OK | OK | OK |
| 30 μm | OK | OK | OK | OK |
| 35 μm | OK | OK | OK | OK |
| 40 μm | OK | OK | OK | OK |
| 45 μm | OK | OK | NG | NG |
| 50 μm | OK | NG | NG | NG |

Table 2 is shown for describing an acceptable thickness and elastic modulus of the first window adhesive layer W_AL1. Hereinafter, the wording “acceptable” means that a buckling does not occur in the protective layer PLL when the display device DD (see FIG. 3) is folded. That is, the wording “acceptable” means that when the display device DD (see FIG. 3) is folded, an irreversible physical property change may not occur in the protective layer PLL, and the folding reliability of the display device DD (see FIG. 3) may be improved.

Table 2 shows, as an example, experimental results under conditions that a temperature is about −20° C., and the protective layer PLL has a thickness of about 50 μm and has a fixed elastic modulus of about 7 GPa.

The mark “OK” in Table 2 means that a deformation of the protective layer PLL may not occur. The mark “NG” in Table 2 means that a deformation of the protective layer PLL may occur.

Referring to Table 2, the thickness of the first window adhesive layer W_AL1 may vary depending on the elastic modulus of the first window adhesive layer W_AL1. Specifically, when the thickness of the first window adhesive layer W_AL1 is less than about 25 μm, the adhesiveness of the first window adhesive layer W_AL1 may be low. Accordingly, the patterned glass PG and the protective layer PLL may be separated from each other. Thus, in an embodiment, the minimum thickness of the first window adhesive layer W_AL1 may be about 25 μm to prevent such separation. The minimum value of the thickness of the first window adhesive layer W_AL1 may be constant.

The maximum value of the thickness of the first window adhesive layer W_AL1 may vary depending on the value of the elastic modulus of the first window adhesive layer W_AL1. In a case where the elastic modulus of the first window adhesive layer W_AL1 is about 50 kilopascals (kPa), the maximum value of the thickness of the first window adhesive layer W_AL1 may be about 50 μm. In this case, the thickness of the first window adhesive layer W_AL1 may in a range of be about 25 μm to about 50 μm. Here, the protective layer PLL may not be deformed although the display device DD (see FIG. 3) is folded and unfolded repeatedly. Accordingly, the folding reliability of the display device DD (see FIG. 3) may be improved.

In a case where the elastic modulus of the first window adhesive layer W_AL1 is about 73 kPa, the maximum value of the thickness of the first window adhesive layer W_AL1 may be about 45 μm. In this case, the thickness of the first window adhesive layer W_AL1 may be in a range about 25 μm to about 45 μm. Here, the protective layer PLL may not be deformed although the display device DD (see FIG. 3) is folded and unfolded repeatedly, and thus the folding reliability of the display device DD (see FIG. 3) may be improved.

In a case where the elastic modulus of the first window adhesive layer W_AL1 is about 88 kPa to about 127 kPa, the maximum thickness of the first window adhesive layer W_AL1 may be about 40 μm. In this case, the thickness of the first window adhesive layer W_AL1 may be in a range of about 25 μm to about 40 μm. Here, the protective layer PLL may not be deformed although the display device DD (see FIG. 3) is folded and unfolded repeatedly. Accordingly, the folding reliability of the display device DD (see FIG. 3) may be improved.

As shown in Table 2, it is confirmed that the maximum value of the thickness of the first window adhesive layer W_AL1 may vary in inverse proportion to the value of the elastic modulus of the first window adhesive layer W_AL1. That is, the thickness of the first window adhesive layer W_AL1 may vary depending on the elastic modulus of the first window adhesive layer W_AL1.

TABLE 3

| Thickness | | | | | | |
|---|---|---|---|---|---|---|
| of first | | | | | | |
| window | | | | | | |
| adhesive | | | | | | |
| layer | Elastic modulus of protective layer (GPa) | | | | | |
| (μm) | 4.3 GPa | 5 GPa | 5.16 GPa | 6 GPa | 7 GPa | 10 GPa |
| 35 μm | NG | OK | OK | OK | OK | OK |
| 40 μm | NG | NG | NG | OK | OK | OK |
| 45 μm | NG | NG | NG | NG | OK | OK |
| 50 μm | NG | NG | NG | NG | NG | OK |

Table 3 shows a relationship between the thickness of the first window adhesive layer W_AL1 and the elastic modulus of the protective layer PLL when the elastic modulus of the first window adhesive layer W_AL1 is about 73 kPa. Table 3 shows, as an example, experimental results under conditions that the thickness of the protective layer is about 50 μm at a temperature of about −20° C.

The mark “OK” in Table 3 means that a deformation of the protective layer PLL may not occur. The mark “NG” in Table 3 means that a deformation of the protective layer PLL may occur.

Referring to Table 3, the range of the elastic modulus of the protective layer PLL may vary depending on the thickness of the first window adhesive layer W_AL1. The maximum value of the elastic modulus of the protective layer PLL producible in a process may be about 10 GPa. Accordingly, the maximum value of the elastic modulus of the protective layer PLL may be about 10 GPa. The maximum value of the elastic modulus of the protective layer PLL may be constant.

The minimum value of the elastic modulus of the protective layer PLL may vary depending on the thickness of the first window adhesive layer W_AL1. Specifically, when the elastic modulus of the first window adhesive layer W_AL1 is about 73 kPa and the thickness thereof is about 35 μm, the acceptable elastic modulus of the protective layer PLL may be about 5 GPa to about 10 GPa. When the thickness of the first window adhesive layer W_AL1 is about 35 μm and the elastic modulus of the protective layer PLL is about 5 GPa to about 10 GPa, the protective layer PLL may not be deformed although the display device DD (see FIG. 3) is folded. Accordingly, the folding reliability of the display device DD (see FIG. 3) may be improved.

When the elastic modulus of the first window adhesive layer W_AL1 is about 73 kPa and the thickness thereof is about 40 μm, the acceptable elastic modulus of the protective layer PLL may be about 6 GPa to about 10 GPa. Here, the protective layer PLL may not be deformed although the display device DD (see FIG. 3) is folded. Accordingly, the folding reliability of the display device DD (see FIG. 3) may be improved.

When the elastic modulus of the first window adhesive layer W_AL1 is about 73 kPa and the thickness thereof is about 45 μm, the acceptable elastic modulus of the protective layer PLL may be in a range of about 7 GPa to about 10 GPa. Here, the protective layer PLL may not be deformed although the display device DD (see FIG. 3) is folded. Accordingly, the folding reliability of the display device DD (see FIG. 3) may be improved.

When the elastic modulus of the first window adhesive layer W_AL1 is about 73 kPa and the thickness thereof is about 50 μm, the acceptable elastic modulus of the protective layer PLL may be more than about 7 GPa and equal to or less than about 10 GPa. Here, when the elastic modulus of the protective layer PLL is about 7 GPa or less, a deformation of the protective layer PLL may occur during the folding of the display device DD (see FIG. 3). Accordingly, a defect of the display device DD (see FIG. 3) may occur.

As shown in Table 3, it is confirmed that the minimum value of the elastic modulus of the protective layer PLL may vary in proportion to the thickness of the first window adhesive layer W_AL1. As the thickness of the protective layer PLL increases, the minimum value of the acceptable elastic modulus of the protective layer PLL may increase. That is, a range of the acceptable elastic modulus of the protective layer PLL may decrease.

TABLE 4

| Thickness of first | | | | |
|---|---|---|---|---|
| window adhesive | Elastic modulus of protective layer (GPa) | | | |
| layer (μm) | 5.16 GPa | 6 GPa | 7 GPa | 10 GPa |
| 35 μm | NG | OK | OK | OK |
| 40 μm | NG | NG | OK | OK |
| 45 μm | NG | NG | NG | OK |
| 50 μm | NG | NG | NG | NG |

Table 4 shows a relationship between the thickness of the first window adhesive layer W_AL1 and the elastic modulus of the protective layer when the elastic modulus of the first window adhesive layer W_AL1 is about 127 kPa. Table 4 shows experimental results under conditions that the thickness of the protective layer is about 50 μm at a temperature of about −20° C.

The mark “OK” in Table 4 means that a deformation of the protective layer PLL may not occur. The mark “NG” in Table 4 means that a deformation of the protective layer PLL may occur.

Referring to Table 4, the elastic modulus of the protective layer PLL may vary depending on the thickness of the first window adhesive layer W_AL1. The maximum value of the elastic modulus of the protective layer PLL producible in a process may be about 10 GPa. Accordingly, the maximum value of the elastic modulus of the protective layer PLL may be about 10 GPa. The maximum value of the elastic modulus of the protective layer PLL may be fixed.

The minimum value of the elastic modulus of the protective layer PLL may vary depending on the thickness of the first window adhesive layer W_AL1. Specifically, when the elastic modulus of the first window adhesive layer W_AL1 is about 127 kPa and the thickness thereof is about 35 μm, the acceptable elastic modulus of the protective layer PLL may be in a range of about 6 GPa to about 10 GPa. Here, when the elastic modulus of the protective layer PLL is less than about 6 GPa, a deformation of the protective layer PLL may occur during the folding of the display device DD (see FIG. 3). However, when the elastic modulus of the protective layer PLL is about 6 GPa to about 10 GPa, the protective layer PLL may not be deformed although the display device DD (see FIG. 3) is folded and unfolded repeatedly. Accordingly, the folding reliability of the display device DD (see FIG. 3) may be improved.

When the elastic modulus of the first window adhesive layer W_AL1 is about 127 kPa and the thickness thereof is about 40 μm, the acceptable elastic modulus of the protective layer PLL may be about 7 GPa to about 10 GPa. Here, when the elastic modulus of the protective layer PLL is less than 7 GPa, a deformation of the protective layer PLL may occur during the folding of the display device DD (see FIG. 3). However, when the elastic modulus of the protective layer PLL is in a range of about 7 GPa to about 10 GPa, the protective layer PLL may not be deformed although the display device DD (see FIG. 3) is folded and unfolded repeatedly. Accordingly, the folding reliability of the display device DD (see FIG. 3) may be improved.

When the elastic modulus of the first window adhesive layer W_AL1 is about 127 kPa and the thickness thereof is about 45 μm, the acceptable elastic modulus of the protective layer PLL may be more than about 7 GPa and equal to or less than about 10 GPa. Here, when the elastic modulus of the protective layer PLL is about 7 GPa or less, a deformation of the protective layer PLL may occur during the folding of the display device DD (see FIG. 3). In an embodiment, the elastic modulus of the protective layer PLL is more than about 7 GPa and equal to or less than about 10 GPa, such that the protective layer PLL may not be deformed although the display device DD (see FIG. 3) is folded and unfolded repeatedly. Accordingly, the folding reliability of the display device DD (see FIG. 3) may be improved.

According to Table 4, as the thickness of the first window adhesive layer W_AL1 increases, the minimum value of the elastic modulus of the protective layer PLL may increase. That is, the minimum value of the elastic modulus of the protective layer PLL may vary in proportion to the thickness of the first window adhesive layer W_AL1.

By comparing Table 3 with Table 4, a relationship between the elastic modulus of the first window adhesive layer W_AL1 and the elastic modulus of the protective layer PLL may be understood. The minimum value of the elastic modulus of the protective layer PLL may increase in proportion to the elastic modulus of the first window adhesive layer W_AL1. As the elastic modulus of the first window adhesive layer W_AL1 increases, the minimum value of the acceptable elastic modulus of the protective layer PLL may increase. The maximum value of the elastic modulus of the protective layer PLL may be fixed.

In an embodiment, where the thickness of the first window adhesive layer W_AL1 is about 35 μm and the elastic modulus thereof is about 73 kPa, a range of the acceptable elastic modulus of the protective layer PLL may be about 5 GPa to about 10 GPa. in an embodiment where the thickness of the first window adhesive layer W_AL1 is about 35 μm and the elastic modulus thereof is about 127 kPa, a range of the acceptable elastic modulus of the protective layer may be about 6 GPa to about 10 GPa.

From the results above, it is confirmed that when the first window adhesive layer W_AL1 has a same thickness, the minimum value of the acceptable elastic modulus of the protective layer PLL may increase as the elastic modulus of the first window adhesive layer W_AL1 increases.

Referring to FIG. 8, the second window adhesive layer W_AL2 may be disposed on the bottom surface of the patterned glass PG. The second window adhesive layer W_AL2 may be disposed between the patterned glass PG and the anti-reflective layer RPL. The patterned glass PG and the anti-reflective layer RPL may be bonded to each other by the second window adhesive layer W_AL2.

The second window adhesive layer W_AL2 may include a PSA, an OCA, or an OCR.

The display device DD (see FIG. 3) may further include a first adhesive layer AF1. The first adhesive layer AF1 may be disposed on the bottom surface of the anti-reflective layer RPL. The first adhesive layer AF1 may be disposed between the anti-reflective layer RPL and the display module DM. The anti-reflective layer RPL and the display module DM may be bonded to each other by the first adhesive layer AF1.

The display device DD (see FIG. 3) may further include a second adhesive layer AF2. The second adhesive layer AF2 may be disposed on the bottom surface of the display module DM. The second adhesive layer AF2 may be disposed between the display module DM and the protective film PF. The display module DM and the protective film PF may be bonded to each other by the second adhesive layer AF2.

The lower film UF may be disposed on the bottom surface of the protective film PF. The lower film UF may include a flexible plastic material such as polyimide (PI).

TABLE 5

| | Thickness of lower film | | Thickness of lower film | | Thickness of lower film | |
|---|---|---|---|---|---|---|
| | (30 μm) | | (35 μm) | | (40 μm) | |
| Elastic | Deformation | | Deformation | | Deformation | |
| modulus | rate of | Deformation | rate of | Deformation | rate of | Deformation |
| of lower | protective | rate of lower | protective | rate of lower | protective | rate of lower |
| film | film | film | film | film | film | film |
| (UF) | (%) | (%) | (%) | (%) | (%) | (%) |
| 1.5 GPa | 3.56 | 5.98 | 3.52 | 6.03 | 3.48 | 6.11 |
| 2 GPa | 3.47 | 5.19 | 3.43 | 5.26 | 3.43 | 5.26 |
| 3 GPa | 3.37 | 4.52 | 3.31 | 4.59 | 3.31 | 4.59 |
| 4 GPa | 3.29 | 4.09 | 3.24 | 4.17 | 3.24 | 4.17 |
| 5 GPa | 3.23 | 3.79 | 3.18 | 3.87 | 3.18 | 3.87 |
| 6 GPa | 3.18 | 3.56 | 3.12 | 3.64 | 3.12 | 3.64 |
| 7 GPa | 3.11 | 3.29 | 3.05 | 3.38 | 3.05 | 3.38 |
| 10 GPa | 3.02 | 2.99 | 2.97 | 3.09 | 2.94 | 3.22 |

Table 5 shows experimental results showing changes of the protective film PF according to changes in thickness and elastic modulus of the lower film UF when the display device DD (see FIG. 3) is folded. The results in Table 5 may be the deformation rates of the lower film UF and the protective film PF measured at a temperature of −20° C. when the radius of curvature R (see FIG. 5) is about 1.0 mm.

When the display device DD (see FIG. 5) is folded, a crack may occur in the protective film PF if the deformation rate of the protective film PF is more than about 3.5%. Accordingly, the lower film UF may be disposed under the protective film PF to reduce the deformation rate of the protective film PF. In an embodiment, the thickness and elastic modulus of the lower film UF may be set in a way such that the deformation rate of the protective film PF is less than about 3.5% to prevent a crack from occurring in the protective film PF.

The maximum value of the elastic modulus of the lower film UF producible in a process may be about 10 GPa. Accordingly, the maximum value of the elastic modulus of the lower film UF may be about 10 GPa. The minimum value of the elastic modulus of the lower film UF may be about 2 GPa in a case where the thickness of the lower film UF is in a range about 30 μm to about 40 μm.

Specifically, referring to Table 5, when the elastic modulus of the lower film UF is less than 2 GPa and the thickness of the lower film UF is about 40 μm, the deformation rate of the protective film PF is about 3.48%. However, when the thickness of the lower film UF is in a range of about 30 μm to about 35 μm, the deformation rate of the protective film PF may be more than about 3.5%. Accordingly, a crack may occur in the protective film PF.

When the elastic modulus of the lower film UF is in a range of about 2 GPa to about 10 GPa and the thickness of the lower film UF is in a range of about 30 μm to about 40 μm, the deformation rate of the protective layer PF may be less than about 3.5%. The deformation rate of the protective film PF may be in inverse proportion to the elastic modulus of the lower film UF.

For example, when the elastic modulus of the lower film UF is about 2 GPa and the thickness thereof is about 30 μm, the deformation rate of the protective film PF may be about 3.47%. When the elastic modulus of the lower film UF is about 2 GPa and the thickness thereof is about 40 μm, the deformation rate of the protective film PF may be about 3.43%. Accordingly, since the deformation rate of the protective film PF is less than about 3.5%, a crack may not occur in the protective film PF.

For example, when the elastic modulus of the lower film UF is about 10 GPa and the thickness thereof is about 30 μm, the deformation rate of the protective film PF may be about 3.02%. When the elastic modulus of the lower film UF is about 10 GPa and the thickness thereof is about 40 μm, the deformation rate of the protective film PF may be about 2.94%. Accordingly, since the deformation rate of the protective film PF is less than about 3.5%, a crack may not occur in the protective film PF.

Thus, from Table 5, it is confirmed that the elastic modulus of the lower film UF may be in a range of about 2 GPa to about 10 GPa, and the thickness of the lower film UF may be in a range of about 30 μm to about 40 μm.

A third adhesive layer AF3 may be disposed between the lower film UF and the support plates SP1 and SP2. The third adhesive layer AF3 may include a first third adhesive layer (hereinafter, will be referred to as “(3_1)-th adhesive layer”) AF3_1 and a second third adhesive layer (hereinafter, will be referred to as “(3_2)-th adhesive layer”) AF3_2. The (3_1)-th adhesive layer AF3_1 and the (3_2)-th adhesive layer AF3_2 may be disposed spaced apart from each other in the first direction DR1. The (3_1)-th adhesive layer AF3_1 and the (3_2)-th adhesive layer AF3_2 may be disposed respectively corresponding to the first and second non-folding regions NFA1 and NFA2. The (3_1)-th adhesive layer AF3_1 may be disposed overlapping the first non-folding region NFA1, and the (3_2)-th adhesive layer AF3_2 may be disposed overlapping the second non-folding region NFA2.

According to an embodiment of the invention, a display device may include a protective layer disposed on a patterned glass, a window adhesive layer disposed between the patterned glass and the protective layer, and a lower film disposed under the patterned glass. In such an embodiment, the window adhesive layer, the patterned glass, and the protective layer may each have a thickness and elastic modulus in a predetermined range such that a portion of the patterned glass, a portion the window adhesive layer, a portion the protective layer, and a portion the lower film, which overlap a folding region, are not deformed. Accordingly, the folding reliability of the display device may be improved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel;
a patterned glass disposed on the display panel, wherein the patterned glass includes a first non-patterned portion, a patterned portion, and a second non-patterned portion, which are sequentially arranged in a first direction;
a protective layer disposed on the patterned glass; and
a first window adhesive layer disposed between the patterned glass and the protective layer,
wherein the protective layer has an elastic modulus in a predetermined range, a maximum value of the elastic modulus of the protective layer is constant, and a minimum value thereof varies in proportion to a thickness of the first window adhesive layer.

2. The display device of claim 1, wherein the protective layer has a thickness in a range of about 50 μm to about 60 μm.

3. The display device of claim 1, wherein the first window adhesive layer has an elastic modulus in a range of about 50 kPa to about 127 kPa.

4. The display device of claim 3, wherein the first window adhesive layer has a thickness in a predetermined range,
a minimum value of the thickness of the first window adhesive layer is constant, and
a maximum value of the thickness of the first window adhesive layer varies in inverse proportion to the elastic modulus of the first window adhesive layer.

5. The display device of claim 4, wherein when the elastic modulus of the first window adhesive layer is about 50 kPa, the thickness of the first window adhesive layer is in a range about 25 μm to about 50 μm, and
when the elastic modulus of the first window adhesive layer is about 127 kPa, the thickness of the first window adhesive layer is in a range of about 25 μm to 40 μm.

6. The display device of claim 5, wherein when the thickness of the first window adhesive layer is about 35 μm, the elastic modulus of the protective layer is in a range about 5 GPa to about 10 GPa, and
when the thickness of the first window adhesive layer is about 40 μm, the elastic modulus of the protective layer is in a range of about 6 GPa to about 10 GPa.

7. The display device of claim 3, wherein the minimum value of the elastic modulus of the protective layer varies in proportion to a value of the elastic modulus of the first window adhesive layer.

8. The display device of claim 1, further comprising:
a lower film disposed under the display panel,
wherein the lower film has a thickness in a range of about 30 μm to about 40 μm.

9. The display device of claim 8, wherein the lower film has an elastic modulus in a range of about 2 GPa to about 10 GPa.

10. The display device of claim 1, wherein an elastic modulus of the first non-patterned portion and an elastic modulus of the second non-patterned portion are greater than an elastic modulus of the patterned portion.

11. The display device of claim 10, wherein the patterned portion has an elastic modulus in a range of about 30 MPa to about 2000 MPa.

12. The display device of claim 1, further comprising:
filling patterns disposed in first grooves defined in a top surface of the patterned portion and second grooves defined in a bottom surface of the patterned portion.

13. The display device of claim 12, wherein the first grooves are recessed from the top surface of the patterned portion to the bottom surface of the patterned portion, and the second grooves are recessed from the bottom surface of the patterned portion to the top surface of the patterned portion.

14. A display device comprising:
a display panel including a first non-folding region, a folding region, and a second non-folding region, which are sequentially arranged in a first direction;
a patterned glass disposed on the display panel;
a lower film disposed under the display panel; and
a protective film disposed between the display panel and the lower film,
wherein the folding region is folded with respect to a folding axis parallel to a second direction crossing the first direction,
when the folding region is folded, the patterned glass, the lower film, and the protective film are folded with respect to the folding axis, and
an elastic modulus of the lower film is in inverse proportion to a change rate of a length of the protective film in the first direction before folding and after folding.

15. The display device of claim 14, wherein the lower film has an elastic modulus in a range of about 2 GPa to about 10 GPa.

16. The display device of claim 15, wherein the lower film has a thickness in a range of about 30 μm to about 40 μm.

17. The display device of claim 14, further comprising:
a protective layer disposed on the patterned glass; and
a first window adhesive layer disposed between the patterned glass and the protective layer,
wherein the protective layer has an elastic modulus in a predetermined range, a maximum value of the elastic modulus of the protective layer is constant, and a minimum value thereof varies in proportion to a thickness of the first window adhesive layer.

18. The display device of claim 17, wherein the first window adhesive layer has an elastic modulus in a range of about 50 kPa to about 127 kPa,
the first window adhesive layer has a thickness in a predetermined range,
a minimum value of the thickness of the first window adhesive layer is constant, and
a maximum value of the thickness of the first window adhesive layer varies in inverse proportion to the elastic modulus of the first window adhesive layer.

19. The display device of claim 18, wherein the minimum value of the elastic modulus of the protective layer varies in proportion to the elastic modulus of the first window adhesive layer.

20. The display device of claim 17, wherein the protective layer has a thickness in a range of about 50 μm to about 60 μm.
